(19) United States
(12) Patent Application Publication
(10) Pub. No.: US 2020/0201189 A1
(43) Pub. Date: Jun. 25, 2020

(54) EXPOSURE APPARATUS

(71) Applicant: Industrial Technology Research Institute, Hsinchu (TW)

(72) Inventors: Chien-Hung Lin, Hsinchu County (TW); Yung-Chao Chen, Taichung City (TW); Chih-Wei Hsu, Hsinchu City (TW); Yu-Sheng Lee, Kaohsiung City (TW); Shau-Yin Tseng, Hsinchu County (TW)

(73) Assignee: Industrial Technology Research Institute, Hsinchu (TW)

(21) Appl. No.: 16/424,462

(22) Filed: May 28, 2019

(30) Foreign Application Priority Data
Dec. 22, 2018 (TW) 107146594

(51) Int. Cl. G03F 7/20; G02B 26/10; G02B 26/08

(52) U.S. Cl. CPC G03F 7/702; G02B 26/105; G02B 26/0816; G02B 26/0883; G02B 26/108

(57) ABSTRACT

An exposure apparatus including an optical device set and a substrate carrying platform is provided. The optical device set includes a plurality of light sources, at least one rotating beam deflector and at least one deflector set. The plurality of light sources are configured to emit a plurality of beams. Each deflector set includes a plurality of deflectors. The substrate carrying platform is configured to move an exposed substrate disposed on the substrate carrying platform relative to the optical device set along a relative movement direction. The plurality of beams sequentially travel through the at least one rotating beam deflector and the plurality of deflectors to be projected on the exposed substrate. Trajectories of the plurality of beams projected on the exposed substrate form a plurality of scan lines through rotation of the at least one rotating beam deflector.

### CROSS-REFERENCE TO RELATED APPLICATION

This application claims the priority benefit of Taiwan application serial no. 107146594, filed on Dec. 22, 2018. The entirety of the above-mentioned patent application is hereby incorporated by reference herein and made a part of this specification.

### TECHNICAL FIELD

The technical field relates to an exposure apparatus.

### BACKGROUND

An exposure apparatus is, for example, the equipment serving for exposure during the manufacturing process of a circuit board. A conventional exposure apparatus adopts indirect imaging, i.e., blocking the surface of an exposed substrate with a mask and then exposing the substrate. However, a mask with a circuit pattern is required for such an indirect exposure apparatus, so additional time is required and the cost is also higher. Comparatively, a direct-imaging exposure apparatus does not require a mask, so the time for manufacturing a circuit board is reduced and the cost is also lower. Consequently, the direct-imaging exposure apparatus is becoming the mainstream on the market.

The direct-imaging exposure apparatus utilizes the principle of laser printer. Namely, a beam emitted by a single laser light source sequentially travels through a rotating beam deflector and a condenser lens to be projected on the exposed substrate. However, when the requirement on the resolution of the exposure apparatus is tightened to micrometer level, the single light source exposure framework will face insufficiency of bandwidth and an excessive scan path (magnifying power), which leads to an inflated rotational speed error of the rotating beam deflector. In addition, due to a larger scan range, the light path of the beam is relatively complicated and requires a large amount of error compensation. Consequently, exposure apparatuses with multiple light sources have emerged. The conventional exposure apparatus with multiple light sources scans in a manner in which a rotating axis of the rotating beam deflector is inclined with respect to a relative movement direction of the exposed substrate. However, the inclined rotating axis may result in a mismatch in shapes between the inclined scanning region and the rectangular exposed substrate. As a result, the exposed substrate needs to be additionally moved in order to be entirely exposed, which leads to an increase in exposure time.

### SUMMARY

An exposure apparatus according to an embodiment of the disclosure includes an optical device set and a substrate carrying platform. The optical device set includes a plurality of light sources, at least one rotating beam deflector and at least one deflector set. The plurality of light sources are configured to emit a plurality of beams. The at least one rotating beam deflector is configured to be rotatable and has at least one reflective or refractive surface. Each deflector set includes a plurality of deflectors. The substrate carrying platform is configured to move an exposed substrate disposed on the substrate carrying platform relative to the optical device set along a relative movement direction. The relative movement direction is substantially perpendicular to an extending direction of a rotating axis of the at least one rotating beam deflector. The beams sequentially travel through the at least one rotating beam deflector and the deflectors to be projected on the exposed substrate. Through rotation of the at least one rotating beam deflector, trajectories of the beams projected on the exposed substrate form a plurality of scan lines, and the scan lines are not parallel to the relative movement direction of the exposed substrate.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic perspective view illustrating an exposure apparatus according to a first embodiment of the disclosure.

FIG. 2 illustrates an example of a plurality of scan lines generated by an exposure apparatus according to an embodiment of the disclosure.

FIG. 3 illustrates another example of a plurality of scan lines generated by an exposure apparatus according to an embodiment of the disclosure.

FIG. 4 is a schematic perspective view illustrating an exposure apparatus according to a second embodiment of the disclosure.

FIG. 5 is a schematic perspective view illustrating an exposure apparatus according to a third embodiment of the disclosure.

FIG. 6A is a schematic perspective view illustrating an exposure apparatus according to a fourth embodiment of the disclosure.

FIG. 6B illustrates an example of a plurality of scan lines generated by the exposure apparatus of FIG. 6A.

FIG. 7 is a schematic perspective view illustrating an exposure apparatus according to a fifth embodiment of the disclosure.

FIG. 8 is a schematic perspective view illustrating an exposure apparatus according to a sixth embodiment of the disclosure.

FIGS. 9A, 9B, and 9C are three schematic perspective views illustrating an exposure apparatus according to another embodiment of the disclosure.

### DETAILED DESCRIPTION OF DISCLOSED EMBODIMENTS

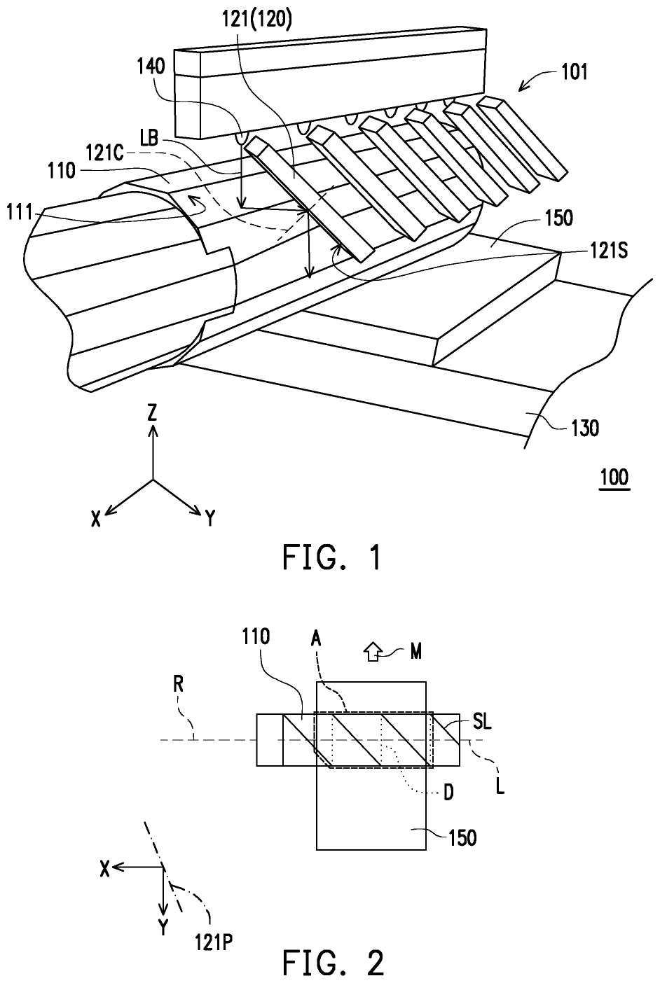

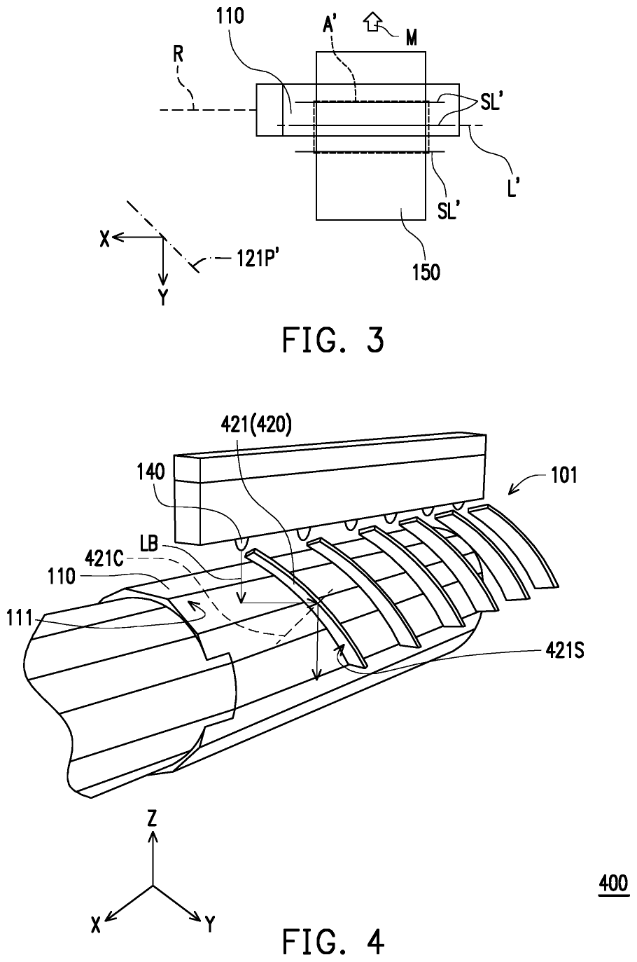

FIG. 1 is a schematic perspective view illustrating an exposure apparatus according to a first embodiment of the disclosure. FIG. 2 illustrates an example of a plurality of scan lines generated by an exposure apparatus according to an embodiment of the disclosure. FIG. 3 illustrates another example of a plurality of scan lines generated by an exposure apparatus according to an embodiment of the disclosure.

Referring to FIGS. 1 and 2, an exposure apparatus 100 of the embodiment includes an optical device set 101 and a substrate carrying platform 130. The optical device set 101 includes a plurality of light sources 140, at least one rotating beam deflector 110 and at least one deflector set 120. The rotating beam deflector 110 is rotatable and has at least one reflective or refractive surface (e.g., a reflective surface 111 shown in FIG. 1). Each deflector set 120 has a plurality of deflectors 121. In this embodiment, each deflector set 120 is a mirror set, and the deflectors 121 are mirrors. However, in other embodiments, each deflector set 120 may be a prism set, and the deflectors 121 may be prisms. The substrate carrying platform 130 is configured to move an exposed substrate 150 disposed on the substrate carrying platform 130 relative to the optical device set 101 along a relative movement direction M.

In the embodiment, the relative movement direction M may be a direction in which, for example, the exposed substrate 150 is moved by the substrate carrying platform 130, and the optical device set 101 remains unmoved. Alternatively, the optical device set 101 is moved in a direction opposite to the relative movement direction M, and the exposed substrate 150 remains unmoved. Or, the exposed substrate 150 is moved by the substrate carrying platform 130, while the optical device set 101 is also moved simultaneously. In other words, the relative movement between the exposed substrate 150 and the optical device set 101 of the exposure apparatus 100 may be designed according to the requirement on exposure. The relative movement direction M is substantially perpendicular to an extending direction of a rotating axis R of the rotating beam deflector 110. However, the disclosure is not limited thereto. The two directions being substantially perpendicular to each other means that the angle included between the two directions is less than five degrees.

The light sources 140 are configured to emit a plurality of beams LB. The light source may be, for example, a laser diode, a solid-state laser, a pulsed laser, or other suitable light source, and the wavelength of the light generated by the light source may be, for example, the wavelength of visible light, infrared light, or light in other suitable wavelengths. The beams LB sequentially travel through the rotating beam deflector 110 and the deflectors 121 to be projected on the exposed substrate 150. Through rotation of the rotating beam deflector 110, trajectories of the beams LB projected on the exposed substrate 150 form a plurality of scan lines SL.

In this embodiment, the extending direction of the rotating axis R is parallel to a plane (e.g., the X-Y plane in FIG. 2) of the exposed substrate 150.

In this embodiment, the scan lines SL are not parallel to the relative movement direction M of the exposed substrate 150. Specifically, directions toward which reflective surfaces 121S of the deflectors 121 face and angles at which the reflective surfaces 121S of the deflectors 121 are set determine the directions and angles of scanning trajectories of the scan lines SL. The user may modify the directions toward which the reflective surfaces 121S of the deflectors 121 face and the angles based on the usage requirement, so as to obtain desired directions and angles of the scanning trajectories of the scan lines SL. Specifically, the reflective surfaces 121S of the deflectors 121 reflect the beams LB toward the exposed substrate 150. In addition, directions of orthogonal projections (e.g., an axis 121P of FIG. 2) of central axes 121C of the deflectors 121 on the exposed substrate 150 are different from the extending direction of the rotating axis R of the at least one rotating beam deflector 110 and the relative movement direction M of the exposed substrate 150. Therefore, extending directions of the scan lines SL are different from the extending direction of the rotating axis R of the rotating beam deflector 110 and the relative movement direction M of the exposed substrate 150.

For example, in FIG. 2, the plane on which the exposed substrate 150 is located on is the X-Y plane, the relative movement direction M is the −Y direction, and the extending direction of the rotating axis R is the X direction. The reflective surfaces 121S of the deflectors 121 reflect the beams LB toward the substrate 150, and the orthogonal projections of the central axes 121C of the deflectors 121 on the exposed substrate 150 are the axes 121P. Slopes of the axes 121P are negative, and acute angles included between the axes 121P and the Y-axis are about 22.5 degrees. Therefore, slopes of the scan lines SL in FIG. 2 are negative, and acute angles included between the scan lines SL and the Y-axis are about 45 degrees.

Referring to FIG. 3, in an embodiment, extending directions of scan lines SL′ are the same as the extending direction of the rotating axis R of the rotating beam deflector 110. For example, the reflective surfaces 121S of the deflectors 121 reflect the beams LB toward the exposed substrate 150, and the orthogonal projections of the central axes 121C of the deflectors 121 on the exposed substrate 150 are axes 121P′. Slopes of the axes 121P′ are negative, and the acute angles included between the axes 121P′ and the Y-axis are about 45 degrees. Therefore, the angles included between the scan lines SL′ and the Y-axis shown in FIG. 3 are about 90 degrees.

In this embodiment, any two adjacent scan lines SL of the scan lines SL are partially overlapped or continuously arranged in the relative movement direction M. In other words, the orthogonal projections of the scan lines SL on the rotating axis R are partially overlapped or form a continuous line. For example, dotted lines D in FIG. 2 illustrate portions where any two adjacent scan lines SL of the scan lines SL are overlapped in the relative movement direction M. The orthogonal projections of the scan lines SL in FIG. 2 on the rotating axis R form a continuous line. For example, orthogonal projections of the scan lines SL′ in FIG. 3 on the rotating axis R are partially overlapped. Compared with the conventional technique, since any two adjacent scan lines SL (or SL′) of the scan lines SL (or SL′) of the exposure apparatus 100 according to the embodiment of the disclosure are partially overlapped or continuously arranged in the relative movement direction M, the exposure apparatus 100 according to the embodiment of the disclosure is suitable for stitching images.

Also, the conventional exposure apparatus performs scanning by making the rotating axis of a rotating mirror inclined with respect to the relative movement direction of the exposed substrate. Therefore, an angle is included between the relative movement direction and a lateral axis of a polygon formed by the intersection between the plane formed by the scan lines of the exposure apparatus and the exposed substrate, such as 45 degrees. In other words, at the times when the scanning of the conventional exposure apparatus is started and finished, the area where the plane formed by the scan lines of the exposure apparatus and the exposed substrate have no intersection is too large, so the conventional exposure apparatus exhibits an excessive increase in exposure time. Comparatively, in the embodiment, the relative movement direction M is substantially perpendicular to the extending direction of the rotating axis R of the rotating beam deflector 110. Therefore, a lateral axis L of a polygon A formed by the intersection between the plane formed by the scan lines SL and the exposed substrate 150 is substantially perpendicular to the relative movement direction M. The lateral axis L being substantially perpendicular to the relative movement direction M means that an absolute value of a value obtained by subtracting 90 degrees from the angle included between the lateral axis L and the relative movement direction M is less than 5 degrees. For example, the lateral axis L of the polygon A formed by the intersection between the plane formed by the scan lines SL of FIG. 2 and the exposed substrate 150 is substantially perpendicular to the relative movement direction M, or a lateral axis L′ of a polygon A′ formed by the intersection between the plane formed by the scan lines SL′ of FIG. 3 and the exposed substrate 150 is substantially perpendicular to the relative movement direction M. Therefore, compared with the conventional art, the exposure apparatus 100 of the embodiment of the disclosure may effectively suppress the increase in scanning time.

Based on the above, since the exposure apparatus 100 according to the embodiment of the disclosure includes the plurality of light sources 140, a range of a scan path of each of the light sources 140 may be effectively controlled within a range of error, and the bandwidth issue of the exposure apparatus 100 with a single light source is alleviated. Moreover, since the scan range of the exposure apparatus 100 is effectively controlled, and the light path of the exposure apparatus 100 is simple, optical compensation may be made digitally, and the manufacturing cost may be reduced. In addition, since the reflective surfaces 121S of the deflectors 121 of the exposure apparatus 100 according to the embodiment of the disclosure reflect the beams toward the exposed substrate 150, and the directions of the orthogonal projections of the central axes 121C of the deflectors 121 on the exposed substrate 150 are different from the extending direction of the rotating axis R of the at least one rotating beam deflector 110 and the relative movement direction M of the exposed substrate 150, the extending directions of the scan lines SL and SL′ are different from the relative movement direction M of the exposed substrate 150, and any two adjacent scan lines SL of the scan lines SL are partially overlapped in the relative movement direction M. Therefore, the exposure apparatus 100 according to the embodiment of the disclosure is suitable for stitching images. Besides, since the relative movement direction M of the exposed substrate 150 is substantially perpendicular to the extending direction of the rotating axis R of the at least one rotating beam deflector 110, the lateral axis L of the polygon A formed by the intersection between the plane formed by the scan lines SL of the exposure apparatus of the embodiment of the disclosure and the exposed substrate 150 is substantially perpendicular to the relative movement direction M. Therefore, the exposure apparatus 100 according to the embodiment of the disclosure may effectively suppress the increase in exposure time.

FIG. 4 is a schematic perspective view illustrating an exposure apparatus according to a second embodiment of the disclosure. Referring to FIG. 4, in the above embodiment, the deflectors 121 of the exposure apparatus 100 are planar mirrors. However, the disclosure is not limited thereto. In an embodiment, a plurality of deflectors 421 in a deflector set 420 are f-theta mirrors, and reflective surfaces 421S of the deflectors 421 are curved surfaces. Therefore, the deflector 421 is suitable for reducing errors of optical path lengths among the beams LB incident to the deflectors 421 at different angles. The f-theta mirror here refers to that the same scanning angle of the beam LB on the f-theta mirror corresponds to the same scanning distance on the exposed substrate 150, regardless of the location (e.g., center, edge, or any other regions) on the f-theta mirror scanned by the beam LB. The principle thereof is similar to the principle of the f-theta scan lens except for a difference that the f-theta scan lens refracts light, and the f-theta mirror reflects light.

Based on the above, an exposure apparatus 400 according to the embodiment of the disclosure exhibits the same properties as those of the exposure apparatus 100. Therefore, details in this regard will not be repeated in the following. Besides, since the exposure apparatus 400 according to the embodiment of the disclosure adopts the f-theta mirror, the exposure apparatus 400 may reduce errors of optical path lengths among the beams LB incident to the deflectors 421 at different angles. Hence, distortion of an exposed image is further suppressed.

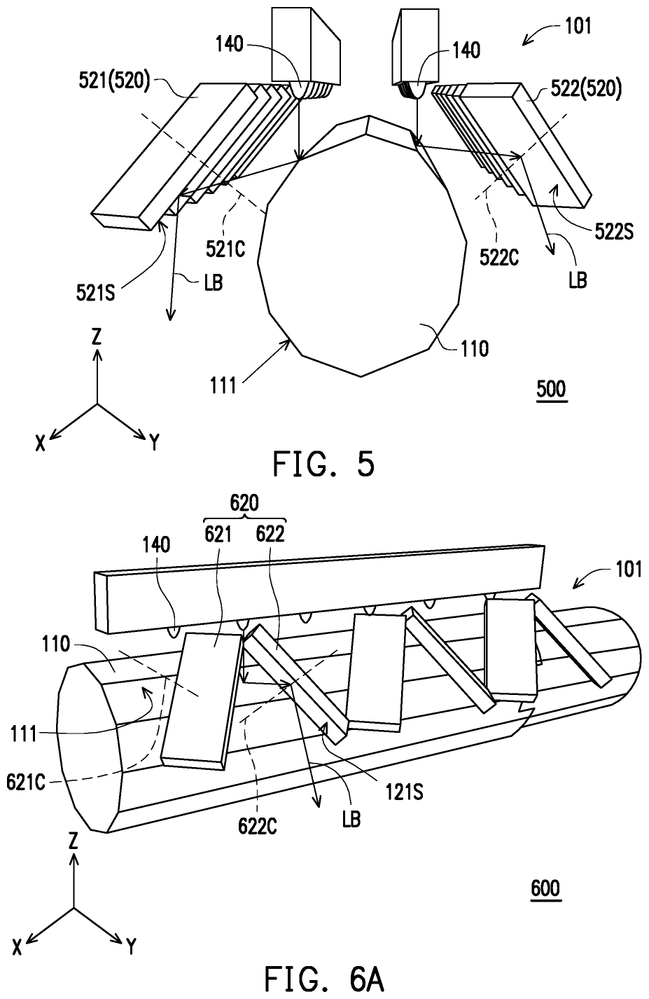

FIG. 5 is a schematic perspective view illustrating an exposure apparatus according to a third embodiment of the disclosure. Referring to FIG. 5, in the above embodiments, the deflectors 121 and 421 of the exposure apparatuses 100 and 400 are disposed on the same side of the rotating axis R of the rotating beam deflector 110. However, the disclosure is not limited thereto. In an embodiment, a plurality of deflectors 521 and 522 (respectively having reflective surfaces 521S and 522S) of a deflector set 520 of an exposure apparatus 500 are disposed on opposite sides of the rotating axis R of the rotating beam deflector 110. For example, in FIG. 5, the deflectors 521 are disposed on a side in the −Y direction perpendicular to the rotating axis R of the rotating beam deflector 110, and the deflectors 522 are disposed on a side in the +Y direction perpendicular to the rotating axis R of the rotating beam deflector 110.

Based on the above, the exposure apparatus 500 according to the embodiment of the disclosure exhibits the same properties as those of the exposure apparatus 100. Therefore, details in this regard will not be repeated in the following. Besides, since the deflectors 521 and 522 of the exposure apparatus 500 according to the embodiment of the disclosure are disposed on opposite sides of the rotating axis R of the rotating beam deflector 110, the exposure apparatus 500 permits a greater extent of flexibility in terms of mechanical design.

FIG. 6A is a schematic perspective view illustrating an exposure apparatus according to a fourth embodiment of the disclosure. FIG. 6B illustrates an example of a plurality of scan lines generated by the exposure apparatus of FIG. 6A. Referring to FIGS. 6A and 6B, in the above embodiment, the directions of the orthogonal projections (e.g., the axis 121P in FIG. 2 or the axis 121P′ in FIG. 3) of the central axes 121C and 421C of the deflectors 121 and 421 in the exposure apparatus 100 and 400 on the exposed substrate 150 are the same as each other. Therefore, the extending directions of the scan lines SL or SL′ are the same as each other. However, the disclosure is not limited thereto. In an embodiment, the directions of the orthogonal projections of the central axes 521C and 522C as well as 621C and 622C of the deflectors 521 and 522 as well as 621 and 622 of the deflector sets 520 and 620 of the exposure apparatuses 500 and 600 on the exposed substrate 150 are different in part. Therefore, the extending directions of the scan lines are different in part (e.g., the extending directions of scan lines SLA and SLB in FIG. 6B are different).

For example, in FIG. 6B, the orthogonal projections of central axes of the deflectors 621 and 622 on the exposed substrate 150 are respectively the axes 621P and 622P. In addition, the slopes of the axes 621P and 622P are respectively positive and negative, and the acute angles included between the axis 621P and Y direction and between the axis 622P and Y direction are about 22.5 degrees. Thus, through rotation of the rotating beam deflector 110, the trajectories of the beams LB projected on the exposed substrate 150 form a plurality of scan lines SLA and SLB. The slopes of the scan line SLA and SLB are respectively positive and negative, and the acute angles included between the scan lines SLA and Y direction and between the scan lines SLB and Y direction are about 45 degrees.

Based on the above, the exposure apparatus 600 according to the embodiment of the disclosure exhibits the same properties as those of the exposure apparatus 100. Therefore, details in this regard will not be repeated in the following. Also, since the directions of the orthogonal projections of the central axes 621C and 622C of the deflectors 621 and 622 of the exposure apparatus 600 according to the embodiment of the disclosure on the exposed substrate 150 are different in part, the extending directions of the scan lines SLA and SLB are different in part and are deviated from and interlaced with each other. Consequently, the exposure apparatus 600 and the exposure apparatus 500 both permit a greater extent of flexibility in terms of mechanical design.

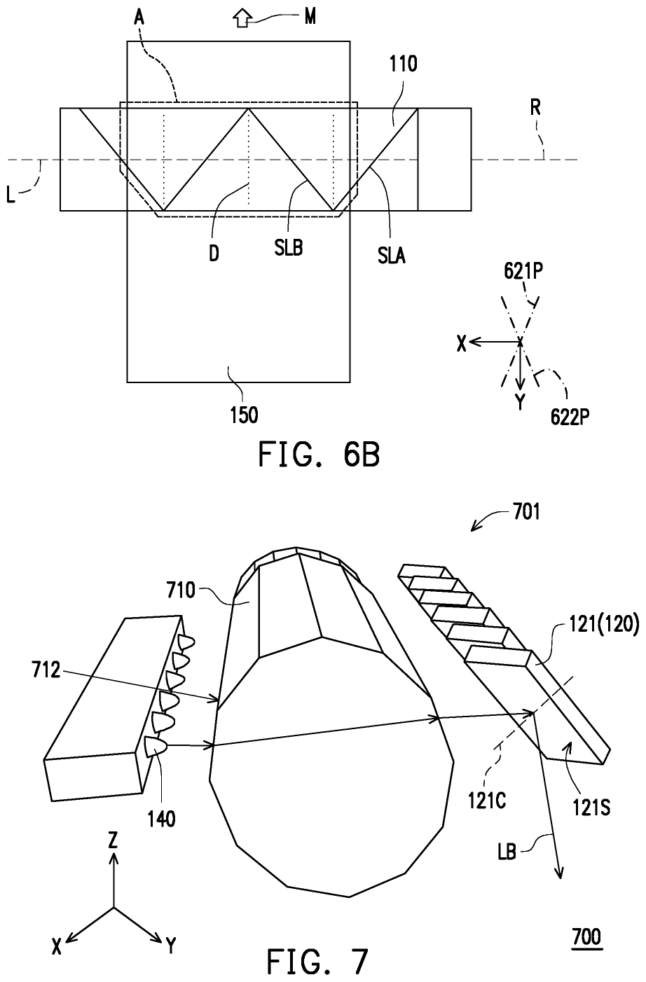

FIG. 7 is a schematic perspective view illustrating an exposure apparatus according to a fifth embodiment of the disclosure. Referring to FIG. 7, in the above embodiments, the rotating beam deflectors 110 in the exposure apparatuses 100, 400, 500, and 600 are reflective rotating mirrors, such as polygon mirrors. For example, in FIG. 1, the beams LB from the light sources 140 are reflected to the deflector set 120 by the rotating beam deflector 110, and the deflector set 120 reflects the beams LB from the rotating beam deflector 110 to the exposed substrate 150. However, the disclosure is not limited thereto. In an embodiment, such as the one shown in FIG. 7, a rotating beam deflector 710 of an optical device set 701 of an exposure apparatus 700 may be a refractive rotating prism, and the rotating beam deflector 710 has at least one refractive surface 712. In other words, the beams LB from the light sources 140 are refracted to the deflector set 120 by the rotating beam deflector 710, and the deflector set 120 reflects the beams LB from the rotating beam deflector 710 to the exposed substrate 150.

Based on the above, the exposure apparatus 700 according to the embodiment of the disclosure exhibits the same properties as those of the exposure apparatus 100. Therefore, details in this regard will not be repeated in the following. In addition, since the rotating beam deflector 710 of the exposure apparatus 700 according to the embodiment of the disclosure is a refractive rotating prism, the thickness of the exposure apparatus 700 in the direction perpendicular to the exposed substrate 150 may be reduced. Consequently, the exposure apparatus 700 may have a smaller size.

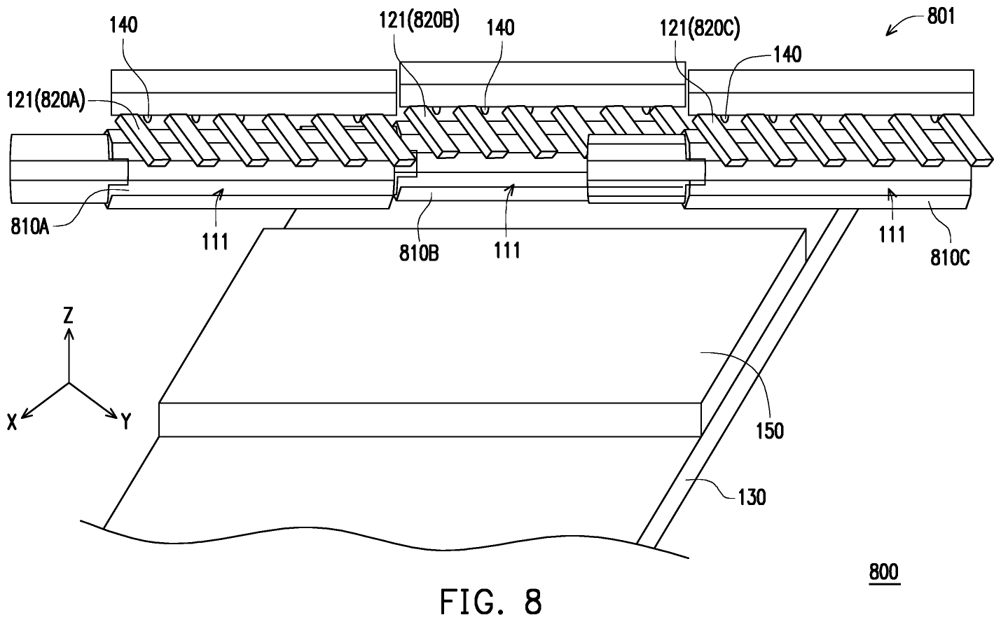

FIG. 8 is a schematic perspective view illustrating an exposure apparatus according to a sixth embodiment of the disclosure. Referring to FIG. 8, in the above embodiments, the exposure apparatus 100, 400, 500, 600, 700 includes only one rotating beam deflector 110 or 710. However, the disclosure is not limited thereto. In an embodiment, the at least one rotating beam deflector may include a plurality of rotating beam deflectors, and the at least one deflector set may include a plurality of deflector sets. The deflector sets respectively correspond to the rotating beam deflectors on the light paths of the beams. For example, an optical device set 801 of an exposure apparatus 800 includes rotating beam deflectors 810A, 810B, and 810C, and deflector sets 820A, 820B, and 820C respectively correspond to the rotating beam deflectors 810A, 810B, and 810C on the light paths of the beams LB.

Based on the above, the exposure apparatus 800 according to the embodiment of the disclosure exhibits the same properties as those of the exposure apparatus 100. Therefore, details in this regard will not be repeated in the following. In addition, since the at least one rotating beam deflector of the exposure apparatus 800 according to the embodiment of the disclosure includes the plurality of rotating beam deflectors 810A, 810B, and 810C, and the at least one deflector set includes the plurality of deflector sets 820A, 820B, and 820C, the exposure apparatus 800 may simultaneously include a plurality of scanning regions. As a result, the exposure area of the exposure apparatus 800 may be further increased.

It should be noted that the plurality of light sources 140 of the exposure apparatuses 100, 400, 500, 600, and 800 are disposed at positions higher than the rotating beam deflectors 100, 810A, 810B, and 810C in the direction perpendicular to the exposed substrate 150. However, the disclosure is not limited thereto. The height of the positions at which the light sources 140 are disposed may be modified according to the design requirement. For example, in FIG. 7, the light sources 140 of the exposure apparatus 700 are disposed on the side of the rotating beam deflector 710, and the height of the light sources 140 in the direction perpendicular to the exposed substrate 150 is lower than the height of the rotating beam deflector 710.

Moreover, the beams LB emitted by the light sources 140 of the exposure apparatuses 100, 400, 500, and 600 of the embodiments are incident at an angle perpendicular to the exposed substrate 150. However, the disclosure is not limited thereto. The incident angles of the beams LB may also be modified according to the design requirement. In other words, the incident angles of the beams LB as well as the angles of the deflectors 120 may be adjusted, so that the trajectories formed by the scan lines SL, SL′, SLA, and SLB of the exposure apparatuses 100, 400, 500, 600, 700, and 800 meet the design requirement.

Besides, the reflective surfaces of the rotating beam deflectors 110, 810A, 810B, and 810C of the exposure apparatuses 100, 400, 500, 600, and 800 are all planar surfaces. However, the disclosure is not limited thereto. The reflective surface of the rotating beam deflector may also be a curved surface according to the design requirement.

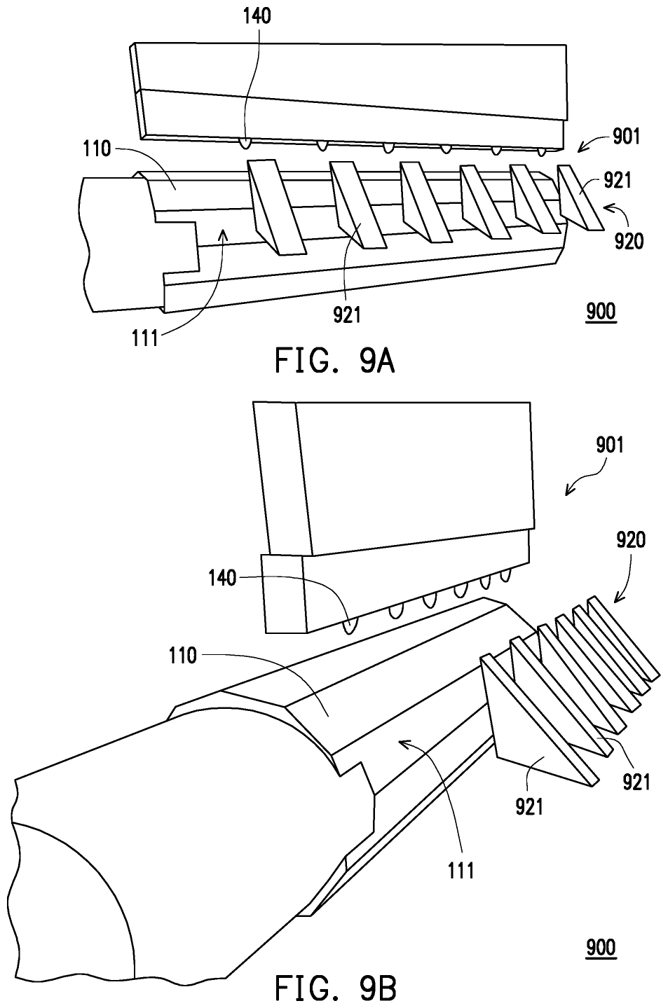

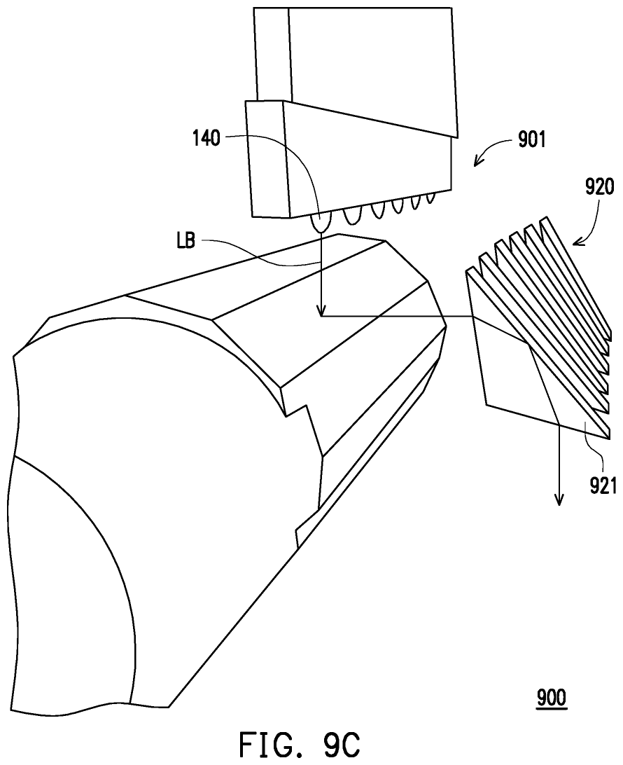

FIGS. 9A, 9B, and 9C are three schematic perspective views illustrating an exposure apparatus according to another embodiment of the disclosure. Referring to FIGS. 9A, 9B, and 9C, the exposure apparatus 900 in this embodiment is similar to the exposure apparatus 100, and the difference therebetween is that the deflector set 120 (i.e. the mirror set) in the exposure apparatus 100 is replaced by a deflector set 920 which is a prism set in the exposure apparatus 900, and the deflectors 121 (i.e. the mirrors) in the exposure apparatus 100 is replaced by deflectors 921 which are prisms (e.g. triangular prisms) in the exposure apparatus 900. The deflectors 921 (i.e. prisms) are capable of refracting and reflecting the beams LB toward the exposed substrate 150. For example, each of the deflectors 921 (i.e. prisms) may refract the beam LB twice and reflect the beam LB once; i.e., two surfaces of each of the deflectors 921 (i.e. prisms) may refract the beam LB, and another surface thereof may reflect the beam LB, as shown in FIG. 9C. However, in other embodiments, the deflectors (i.e. prisms) may refract the beams but not reflect the beams. Alternatively, the deflectors (i.e. prisms) may reflect the beams but not refract the beams. Moreover, the deflectors in all of the aforementioned embodiment may be mirrors or prisms.

In view of the foregoing, since the exposure apparatus according to one or more embodiments of the disclosure includes the plurality of light sources, the range of the scan path of each of the light sources may be effectively controlled within the range of error, and the bandwidth issue of the exposure apparatus with a single light source is effectively alleviated. Moreover, since the scan range of the exposure apparatus is effectively controlled, and the light path of the exposure apparatus is simple, optical compensation may be made digitally, and the manufacturing cost is reduced. In addition, since the reflective surfaces of the deflectors of the exposure apparatus according to one or more embodiments of the disclosure reflect the beams toward the exposed substrate, and the directions of the orthogonal projections of the central axes of the deflectors on the exposed substrate are different from the extending direction of the rotating axis of the rotating beam deflector and the relative movement direction of the exposed substrate, the extending directions of the scan lines are different from the extending direction of the rotating axis of the rotating beam deflector and the relative movement direction of the exposed substrate, and any two adjacent scan lines of the scan lines are partially overlapped or continuously arranged in the relative movement direction. Therefore, the exposure apparatus according to one or more embodiments of the disclosure is suitable for stitching images. Besides, since the relative movement direction of the exposed substrate is substantially perpendicular to the extending direction of the rotating axis of the at least one rotating beam deflector, the lateral axis of the polygon formed by the intersection between the plane formed by the scan lines of the exposure apparatus according to one or more embodiments of the disclosure and the exposed substrate is substantially perpendicular to the relative movement direction. Therefore, the exposure apparatus according to one or more embodiments of the disclosure may effectively suppress the increase in exposure time.

Besides, since the exposure apparatus according to one or more embodiments of the disclosure adopts the f-theta mirror, the exposure apparatus may reduce the errors of optical path lengths among the beams incident to the deflectors at different angles. Hence, distortion of an exposed image is further suppressed. Moreover, since the plurality of deflectors of the exposure apparatus according to one or more embodiments of the disclosure are disposed on opposite sides of the rotating axis of the rotating beam deflector, and the directions of the orthogonal projections of the central axes of the deflectors in the exposure apparatus according to one or more embodiments of the disclosure on the exposed substrate are different in part, the extending directions of the scan lines are different in part and are deviated from and interlaced with each other. Therefore, the exposure apparatus permits a greater extent of flexibility in terms of mechanical design. Furthermore, since the rotating beam deflector of the exposure apparatus according to one or more embodiments of the disclosure is a refractive rotating prism, the thickness of the exposure apparatus in the direction perpendicular to the exposed substrate may be reduced. Therefore, the exposure apparatus may have a smaller size. Besides, since the at least one rotating beam deflector of the exposure apparatus according to one or more embodiments of the disclosure includes the plurality of rotating beam deflectors and the at least one deflector set includes the plurality of deflector sets, the exposure apparatus may simultaneously include the plurality of scanning regions. As a result, the scanning area of the exposure apparatus may be further increased. Also, since the positions at which the plurality of light sources of the exposure apparatus according to one or more embodiments of the disclosure are disposed may be modified according to the design requirement, and the surface of the rotating beam deflector is not limited to a planar surface, the exposure apparatus is permitted with a greater extent of flexibility in terms of the light path design.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An exposure apparatus, comprising:
an optical device set, comprising:
a plurality of light sources, configured to emit a plurality of beams;
at least one rotating beam deflector, configured to be rotatable and having at least one reflective or refractive surface; and
at least one deflector set, wherein each of the at least one deflector set comprises a plurality of deflectors; and
a substrate carrying platform, configured to move an exposed substrate disposed on the substrate carrying platform relative to the optical device set along a relative movement direction, wherein the relative movement direction is substantially perpendicular to an extending direction of a rotating axis of the at least one rotating beam deflector, the beams sequentially travel through the at least one rotating beam deflector and the deflectors to be projected on the exposed substrate, and through rotation of the at least one rotating beam deflector, trajectories of the beams projected on the exposed substrate form a plurality of scan lines, and the scan lines are not parallel to the relative movement direction of the exposed substrate.

2. The exposure apparatus as claimed in claim 1, wherein any two adjacent scan lines of the scan lines are partially overlapped or arranged continuously in the relative movement direction.

3. The exposure apparatus as claimed in claim 1, wherein the extending direction of the rotating axis is parallel to a plane of the exposed substrate.

4. The exposure apparatus as claimed in claim 1, wherein the deflectors are f-theta mirrors.

5. The exposure apparatus as claimed in claim 1, wherein the at least one rotating beam deflector is a reflective rotating mirror.

6. The exposure apparatus as claimed in claim 1, wherein the at least one rotating beam deflector is a refractive rotating prism.

7. The exposure apparatus as claimed in claim 1, wherein reflective surfaces of the deflectors reflect the beams toward the exposed substrate, and directions of orthogonal projections of central axes of the deflectors on the exposed substrate are different from the extending direction of the rotating axis of the at least one rotating beam deflector and the relative movement direction of the exposed substrate.

8. The exposure apparatus as claimed in claim 1, wherein extending directions of the scan lines are different from the extending direction of the rotating axis of the at least one rotating beam deflector and the relative movement direction of the exposed substrate.

9. The exposure apparatus as claimed in claim 1, wherein extending directions of the scan lines are the same as the extending direction of the rotating axis of the at least one rotating beam deflector.

10. The exposure apparatus as claimed in claim 1, wherein the deflectors are disposed on a same side of the rotating axis of the at least one rotating beam deflector.

11. The exposure apparatus as claimed in claim 1, wherein the deflectors are disposed on two opposite sides of the rotating axis of the at least one rotating beam deflector.

12. The exposure apparatus as claimed in claim 1, wherein directions of orthogonal projections of central axes of the deflectors on the exposed substrate are the same as each other.

13. The exposure apparatus as claimed in claim 12, wherein extending directions of the scan lines are the same as each other.

14. The exposure apparatus as claimed in claim 1, wherein directions of orthogonal projections of central axes of the deflectors on the exposed substrate are different in part.

15. The exposure apparatus as claimed in claim 14, wherein extending directions of the scan lines are different in part.

16. The exposure apparatus as claimed in claim 1, wherein the at least one rotating beam deflector comprises a plurality of rotating beam deflectors, the at least one deflector set comprises a plurality of deflector sets, and the deflector sets respectively correspond to the rotating beam deflectors on light paths of the beams.
